(19) United States
(12) Patent Application Publication
(10) Pub. No.: US 2026/0305338 A1
(43) Pub. Date: Oct. 1, 2026

(54) DEVICES AND METHODS INVOLVING HEAT-DISSIPATION VIA ENGINEERED INTERLAYER ADJACENT DIAMOND

(71) Applicant: The Board of Trustees of the Leland Stanford Junior University, Stanford, CA (US)

(72) Inventors: Srabanti Chowdhury, San Ramon, CA (US); Mohamadali Malakoutian, Stanford, CA (US); Kelly Woo, Stanford, CA (US); Anna Kasperovich, Stanford, CA (US); Devansh Saraswat, Stanford, CA (US)

(21) Appl. No.: 19/489,786

(22) PCT Filed: Jun. 6, 2024
(86) PCT No.: PCT/US2024/032868

§ 371 Date: Dec. 3, 2025

Related U.S. Application Data
(60) Provisional application No. 63/471,822, filed on Jun. 8, 2023.

(51) Int. Cl. H10W 40/25; H10W 40/20; H10W 42/00

(52) U.S. Cl. CPC H10W 40/254; H10W 40/242; H10W 42/121

(57) ABSTRACT

In certain examples, methods and semiconductor structures are directed to an apparatus such as a semiconductor device including a substrate material being susceptible to collecting or generating heat due to nearby electrical conductivity, a diamond material to spread and transfer heat from the substrate material, and an interlayer material located between the substrate material and the diamond material. The interlayer material is characterized by having a TBR (thermal boundary resistance) and having an interlayer-material cross-sectional thinness metric with an upper limit engineered via a material deposition technique to mitigate phonon transport loss for realizing a target or a corresponding TBR associated with the interlayer material.

### BACKGROUND

Aspects of the present disclosure are related generally to the field of device use and manufacture for dissipating heat via diamond, and as may be exemplified by uses of diamond grown around fast-switching, high-powered signal-amplifying semiconductor devices.

Using one such technology type for ease of discussion, it has been appreciated that the existence of highly localized electric fields in transistors produces high-temperature spots, which degrade the performance by lowering carrier mobility and, thus, current. Further increase in the operating voltage for higher power applications results in temperature spikes and premature device failure. An accurately designed and implemented device-level thermal management strategy can reduce the channel/junction temperature in high-power and high-frequency transistors such as GaN RF HEMTs, InP HBTs, and Ga₂O₃ power transistors, and improve the life and operational attributes of such transistors.

Diamond, which is an excellent thermal material with a high TC (thermal conductivity) of 500-2200 W/m/K, can be integrated as close as 1 nm to a device's channel/junction, and has been used to lower the thermal boundary resistance (TBR) between the diamond and the channel (of a transistor) to ~3 m²K/GW. Especially in RF devices, while most of the heat transport is taken care of using ballistic transport, it becomes increasingly challenging to dissipate the heat from the channel/junction. Therefore, a heat spreader such as diamond is integrated as closely as possible without disrupting device performance while it is providing high in-plane and cross-plane TCs.

Besides RF and power transistors, device-level thermal management demands are rising in Si technology as well. To enable the reliable operation of high-power integrated circuits (ICs), including 3D integrated circuits for higher speed and higher power computation, without overheating, incorporating heat spreaders in the back-end-of-line (BEoL) process may be important for certain applications and/or design implementations. Although recently developed heat-sink technologies like porous copper may yield heat removal capabilities of 106 W/m²/K, heat transport from hot spots through the BEOL routing within the 3D material stack is still an enormous challenge with current inter-layer dielectric (ILD) material selections. As 3D ICs stack more tiers and heat sinks improve, these thermally resistive materials will eventually have a larger impact on the junction temperature than the heat sink. Here also, polycrystalline diamond, with its comparatively higher TC, can replace part of the existing ultra-low-K ILD (with an extremely low TC of 0.2 W/m/K) to laterally conduct heat to thermal vias or can be added to the power delivery network in flip-chip architecture to reduce overall thermal resistance to the heat sink.

Accordingly, exemplary aspects of the present disclosure are directed to these and other issues concerning removal of heat in and around heat-generating devices including, but not limited to, those described above.

### SUMMARY OF VARIOUS ASPECTS AND EXAMPLES

Various examples/embodiments presented by the present disclosure are directed to issues such as those addressed above and/or others which may become apparent from the following disclosure. For example, some of these disclosed aspects are directed to methods and devices that use diamond in close proximity to hot spots in high-powered/fast-switching transistor technology. Other aspects are directed to overcoming previously-used techniques, such as discussed above, by way of a carefully engineered interlayer material, characterized as having a TBR (thermal boundary resistance) and having a cross-sectional dimension between the heat-spreading diamond material and a substrate material manifesting high temperatures such as a channel/junction.

In one specific example, methods and semiconductor structures are directed to an apparatus such as a semiconductor device including: a substrate material being susceptible to collecting or generating heat due to nearby electrical conductivity; a diamond material to spread and transfer heat from the substrate material; and an interlayer material located between the substrate material and the diamond material. The interlayer material is characterized in that it has a TBR and an interlayer-material cross-sectional thinness metric with an upper limit engineered via a material deposition technique to mitigate phonon transport loss for realizing a target or a corresponding TBR associated with the interlayer material.

In certain other examples which may also build on the above-discussed aspects, methods and semiconductor structures are directed to the interlayer material being characterized by at least one smooth transition in material phases to match one or more phonon-related parameters (being phonon group velocity, phonon frequency and phonon mode) on opposing sides of the interlayer material; and/or to the substrate material including a carbon-diffused portion, along a side of the substrate material facing the diamond material, the carbon-diffused portion having a cross section characterized by a thinness parameter in a range from about 1 nm to about 10 nm. In certain other examples which may further build on the above-discussed aspects, methods and semiconductor structures are directed to the interlayer material being characterized as being a dielectric that includes SiC or AlC and/or the interlayer material being formed by a material deposition technique, including a crystalline or amorphous dielectric portion.

The above discussion is not intended to describe each aspect, embodiment or every implementation of the present disclosure. The figures and detailed description that follow also exemplify various embodiments.

### BRIEF DESCRIPTION OF FIGURES

Various example embodiments, including experimental examples, may be more completely understood in consideration of the following detailed description in connection with the accompanying drawings, each in accordance with the present disclosure, in which:

FIG. 1 is cross-section viewgraph of diamond on a substrate with a proper dielectric material interlayer (e.g., including a transition layer), according to certain exemplary aspects of the present disclosure;

FIGS. 2A and 2B are a set of cross-section viewgraphs of heat generation profile of an exemplary switching device showing how the heat penetration depth varies with the frequency of the device operation, with the viewgraph of FIG. 2A showing lower frequency range heating and the viewgraph of FIG. 2B showing higher frequency range heating, also according to certain exemplary aspects of the present disclosure;

FIGS. 3A-1, 3A-2, 3B-1, 3B-2, and 3B-3 are a set of cross-section viewgraphs, according to certain exemplary aspects of the present disclosure;

FIG. 4 is a process-flow diagram by which nanometers-thick thin films may be controllably fabricated and characterized, according to certain exemplary aspects of the present disclosure;

FIGS. 5A, 5B and 5C are a set of TEM images showing realization of engineered interlayers, according to certain exemplary aspects of the present disclosure;

FIG. 6 is a TEM image, of an example experimental device highlighting a C/Si interface after exposure to an ion beam, according to certain exemplary aspects of the present disclosure;

FIGS. 7A and 7B are a set of diagrams characterizing thermal behavior of an example experimental device with a particular experimental interlayer, according to certain exemplary aspects of the present disclosure, with FIG. 7A showing a graph of differing thermal boundary resistances vs. diamond thicknesses, and FIG. 7B showing EELS characterization of the interlayer;

FIGS. 8A, 8 B, and 8C are a set of images showing EELS analysis with cross-sectional views of different experimental samples respectively shown in each respective figure, according to certain exemplary aspects of the present disclosure;

FIG. 9 is a graph showing thermal boundary resistance vs. interlayer thickness associated with different experimental samples, according to certain exemplary aspects of the present disclosure;

FIG. 10 is a graph showing electro-thermal simulation of a GaN HEMT, for three cases, according to certain exemplary aspects of the present disclosure;

FIG. 11 is an example of a layered system, also according to certain exemplary aspects of the present disclosure;

FIG. 12 is a graph, according to certain exemplary aspects of the present disclosure, showing simulation results of abrupt interfaces for: diamond/Si, SiC/Si, and diamond/SiC (shown as 0 nm interlayer thickness for purposes of illustration);

FIGS. 13A and 13B are respective viewgraphs of a Si integrated circuit (“IC”) as in FIG. 13A and a GaN power amplifier IC as in FIG. 13B, according to certain exemplary aspects of the present disclosure;

FIGS. 14A and 14B are TEM images of diamond grown on differently treated substrates, according to certain exemplary aspects of the present disclosure; and

FIG. 15 is a graph showing TBR versus interlayer thickness, according to certain exemplary aspects of the present disclosure.

While various embodiments discussed herein are amenable to modifications and alternative forms, aspects thereof have been shown by way of example in the drawings and will be described in detail. It should be understood, however, that the intention is not to limit the disclosure to the particular embodiments described. On the contrary, the intention is to cover all modifications, equivalents, and alternatives falling within the scope of the disclosure including aspects defined in the claims. In addition, the term “example” as used throughout this application is only by way of illustration, and not limitation.

### DETAILED DESCRIPTION

Aspects of the present disclosure are believed to be applicable to a variety of different types of apparatuses, systems and methods involving devices characterized at least in part by a diamond material to spread and transfer heat, from heat or a hot spot in a substrate material, via an engineered thin interlayer material located between the substrate material and the diamond material. While the present disclosure is not necessarily limited to such aspects, an understanding of specific examples in the following description may be understood from discussion in such specific contexts.

Accordingly, in the following description various specific details are set forth to describe specific examples presented herein. It should be apparent to one skilled in the art, however, that one or more other examples and/or variations of these examples may be practiced without all the specific details given below. In other instances, well-known features have not been described in detail so as not to obscure the description of the examples herein. For ease of illustration, the same connotation and/or reference numerals may be used in different diagrams to refer to the same elements or additional instances of the same element. Also, although aspects and features may in some cases be described in individual figures, it will be appreciated that features from one figure or embodiment can be combined with features of another figure or embodiment even though the combination is not explicitly shown or explicitly described as a combination.

Exemplary aspects of the present disclosure are related to an apparatus, such as a semiconductor device or other heat-generating/heat-collecting structure, and to dissipation of such heat through use of a diamond material and a carefully-engineered interlayer, or interfacial layer between the structure or substrate material and the diamond material. The interlayer material is characterized by having a TBR (thermal boundary resistance) and having an interlayer-material cross-sectional thinness metric with an upper limit engineered via a material deposition technique to mitigate phonon transport loss for realizing a target or a corresponding TBR associated with the interlayer material.

Consistent with the above aspects, such a manufactured device or method of such manufacture may involve aspects presented and claimed in U.S. Provisional Application Ser. No. 63/471,822 filed on Jun. 8, 2023 (STFD.455P1 S23-225) with Appendices A-E, to which priority is claimed. To the extent permitted, such subject matter is incorporated by reference in its entirety generally and to the extent that further aspects and examples (such as experimental and/more-detailed embodiments) may be useful to supplement and/or clarify.

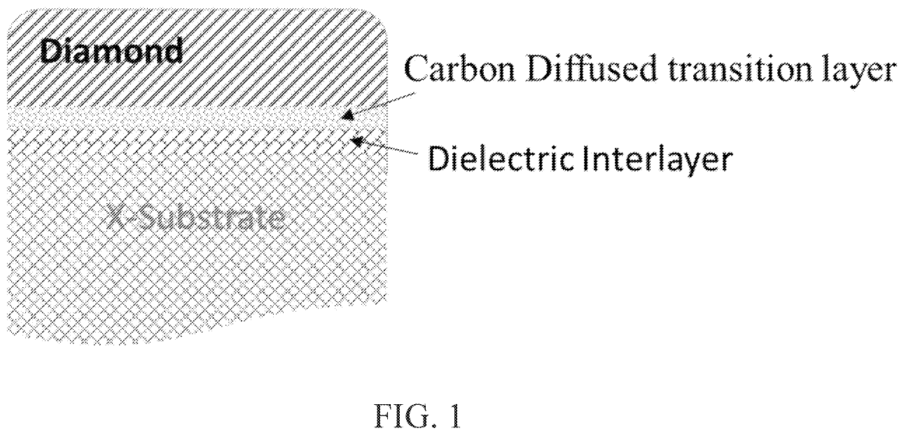

Consistent with certain aspects and applications of example embodiments of the present disclosure, FIG. 1 is cross-section viewgraph of an apparatus having a dielectric interlayer between diamond and a substrate. The substrate, in this example, is depicted as “X-substrate” which may include or be based on, but not limited to, any of a number of different exemplary types of semiconductor materials. For example, in FIG. 1, the X-substrate may include or be based on any one or a combination of: Si, SiC, GaAs, GaN, InP, and β-Ga₂O₃. The dielectric interlayer of FIG. 1, optionally, may have a carbon-diffused transition layer (e.g., SiC or Al₄C₃), as depicted along the upper surface of the dielectric interlayer and immediately adjacent the diamond.

Use of such a dielectric interlayer has been experimentally demonstrated as being particularly important as a thermal-management strategy to reduce channel/junction temperatures in high-power and high-frequency transistors such as GaN RF HEMTs, InP HBTs, and Ga₂O₃ power transistors. Proper thermal management in this way has been shown to increase the lifetime of such transistors and shift the failure point to higher powers and frequencies. Furthermore, in connection with experimental efforts leading up to the present disclosure, use of such a dielectric interlayer has been experimentally demonstrated as being particularly important to help maintain high current levels by increasing the heat transfer coefficient from the channel to the heat spreader material. With diamond used in such experimental efforts as the thermal material (e.g., with a high TC of 500-2200 W/m/K) and integrated as close as 1 nm to the channel/junction, the thermal boundary resistance (TBR) between the diamond and the channel has been lowered to less than ~3 m²K/GW.

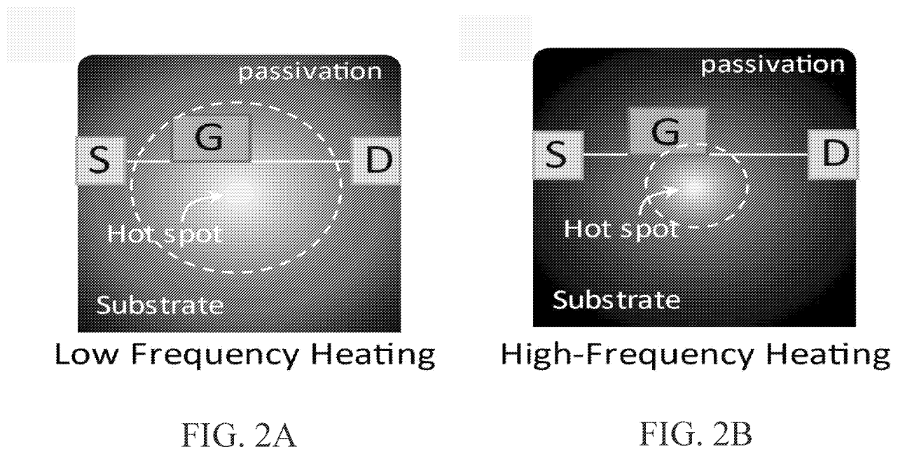

FIGS. 2A and 2B are useful in realizing how frequency affects heat penetration depth, with the heat penetration depth varying based on the frequency of the device in operation. FIG. 2A shows low-frequency heating with a hot spot in the center and extending up to the dotted line and with the region outside the dotted line shown the heat spreading via passivation. In contrast, FIG. 2B shows high-frequency heating with a reduced-center portion showing a hot spot and extending outwardly to cover a region confined within dotted lines showing a smaller circumference (and with the region outside the dotted line again showing the heat spreading via passivation). For such high-power and/or high-frequency transistors as in FIG. 2B, heat generation in the channel/junction at higher frequencies, lowers the heat penetration depth significantly through diffusive phonon transport

$$( {L}_{p} = \sqrt{\frac{k}{C π f}} )$$

and produces more localized hot spots. Thus, the exemplary thermal-management strategy as shown in FIG. 1 is especially advantageous in such RF devices which oftentimes use high-power and/or high-frequency transistors, where it is difficult to dissipate the heat from the channel/junction. In certain more-particular examples according to the present disclosure, it is therefore preferred that the heat spreader (the diamond material) is integrated as closely as possible to the hot spot without disrupting device performance while it is providing high in-plane and cross-plane TCs.

Whether RF devices, power transistors or other types of heat-producing structures such as Si technology, device-level thermal management according to the present disclosure is advantageous in reducing the thermal boundary resistance between the diamond and the hot spot of the underlying (e.g., the device channel/junction) material. By using a carefully-engineered interlayer, as exemplified above, a proper buffer is provided as the interface, or interfacial layer, to lessen or minimize differences in phonons frequency and group velocity between the two materials, thereby reducing the TBR. According to examples of the present disclosure, engineering the interface is done in a way that provides a low-loss diffusive or ballistic phonon transport at the interface depending on the heating frequency.

In certain experiments to this end, it has been unexpectedly discovered that an epitaxially abrupt and almost/virtually perfect interface can be realized between diamond and one or more other semiconductors (e.g., Si, GaN, InP, and β-Ga₂O₃) despite such an outcome being extremely difficult due to the lattice mismatch between the two materials. Transmission electron microscopy (TEM), electron energy loss spectroscopy (EELS), and Raman spectroscopy were used in connection with confirming the interface analysis. Engineering the interface, via an interlayer material as exemplified in the above-disclosed examples, is an important step in efficient thermal management according to the present disclosure. More specifically and also according to specific examples of the present disclosure, minimizing or at least substantially reducing the phonon transport loss at the interface for lower or targeted TBR is carried out via interface engineering along with temperature control. This interlayer material is engineered for its chemistry and thinness associated with a specific lower-level (e.g., minimal or targeted) TBR using material deposition(s) and with any appropriate degree of processing (e.g., smoothing or etching) of the upper portion/surface of the deposited material(s). In this way, the interlayer material is engineered for such a specific TBR and an interlayer-material thinness across the interlayer material between the substrate material and the diamond material. Engineered as such, the interlayer-material thinness is in a range (non-limiting example ranges including 1 nm-20 nm, 20 nm-50 nm, among others) with an upper limit controlled by the engineering steps associated with the material-deposition technique to set a thickness dimension and thereby mitigate a degree (or all) of phonon transport loss for realizing the target or a corresponding TBR associated with the interlayer material. Considering Si technology, for example, a large difference between phonon group velocities in Si (5000-8100 m/s) and diamond (14400-18700 m/s) increases the phonon transport loss by reflecting the majority of the phonons. By using such an efficient thermal management strategy as exemplified herein according to examples of the present disclosure, this increased phonon transport loss associated with the lattice mismatch between the two materials is overcome.

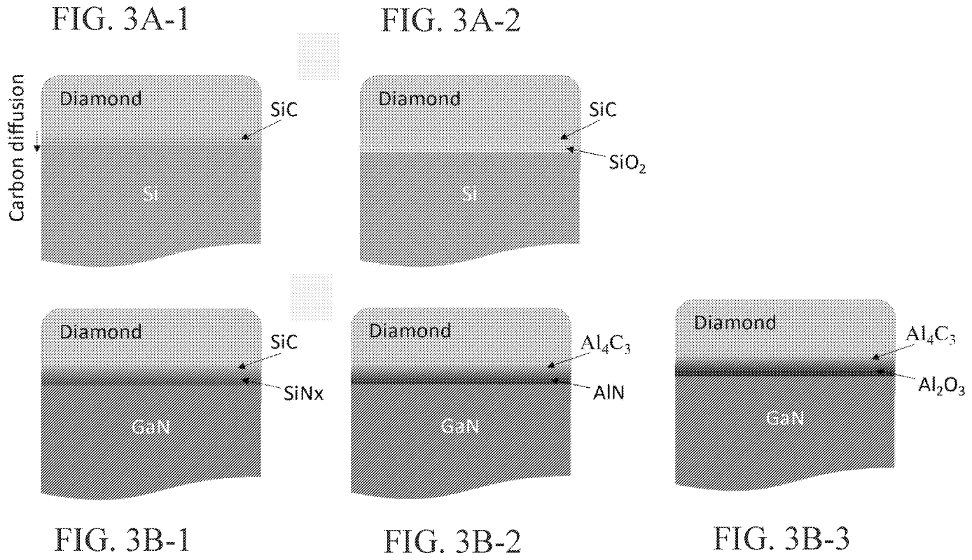

As shown in FIGS. 3A-1 and 3A-2, and in FIGS. 3B-1, 3B-2, and 3B-3, the interface engineering can be implemented during manufacture by adding a buffer layer such as SiC into the interface (at an upper surface of the interlayer) with a larger phonon group velocity (7200-12000 m/s) than Si to create a more gradual transition between phonon properties. In one example experiment according to the present disclosure, to form the interlayer (or buffer), carbon is diffused into the Si substrate during the diamond growth, forming a thin layer of SiC (e.g., one to several atomic layers) which enhances the C—Si bonding strength and provides a smooth transition in the material phases to match one or more phonon-related parameters (being phonon group velocity, phonon frequency and phonon mode) on both sides (FIGS. 3A-1 and 3A-2). For a GaN material system, a thin SiNx layer combined with a SiC interfacial layer act as the phonon buffer layer between diamond and GaN (FIGS. 3B-1, 3B-2 and 3B-3). It has been demonstrated that diamond can be grown on a wide variety, or most any, semiconductor material (such as but not limited to Si, SiC, GaAs, GaN, InP, and β-Ga₂O₃) with a proper interlayer as a phonon transport buffer layer. This interlayer also acts as a stress relief layer which enhances the adhesion force which was caused by lattice and coefficient of thermal expansion (CTE) mismatch. More particularly, FIGS. 3A-1 and 3A-2 respectively show cross-section viewgraphs including an example diamond/Si interface with inter-diffused carbon to make SiC on one side (e.g., on top) of Si and SiO₂/Si substrates as in FIGS. 3A-1 and 3A-2, whereas FIGS. 3B-1, 3B-2 and 3B-3 respectively show diamond/GaN interface with inter-diffused carbon to make SiC on top of SiNx/GaN and Al₄C₃ on top of AlN/GaN, for low-loss phonon transport.

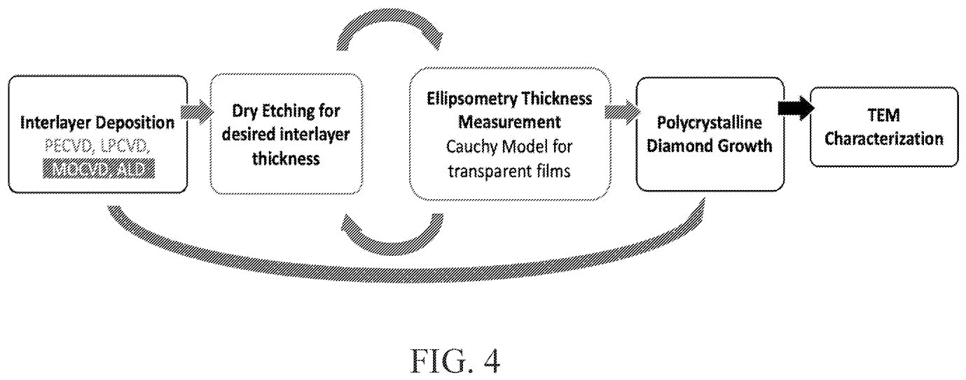

Different steps and/or techniques (aka “interlayer engineering aspects”) may be used separately or together in connection with certain experimental examples according to the present disclosure for engineering exemplary interlayers such as described above. FIGS. 4, 5 and 6 are used to illustrate four examples of engineering aspects for creating such exemplary interlayers, which are: (i) an amorphous and crystalline dielectric deposition; (ii) nanocrystallization and amorphization of the interface using high-energy ion beams; (iii) crystallization of the interface using high-temperature vacuum annealing; and (iv) carbon diffusion during diamond growth. A further engineering aspect, which may also be combined with one or more of the above aspects, is to cause the interlayer material to crystallize during growth of the diamond material.

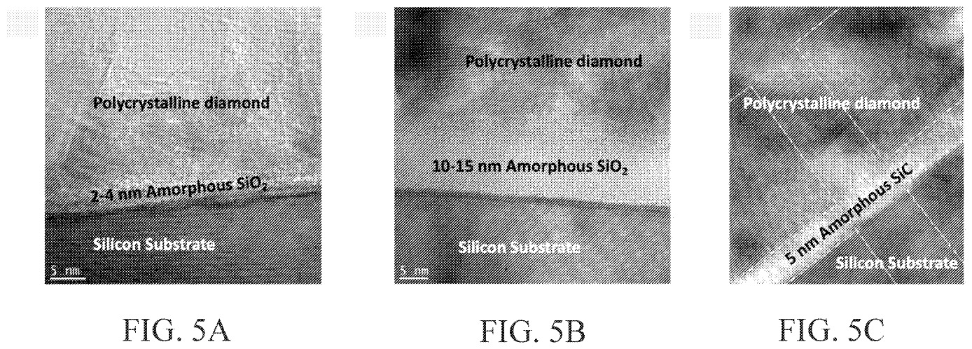

The first exemplary engineering aspect is referred to as amorphous and crystalline dielectric deposition. In this aspect, a combination of ALD, MOCVD, PECVD, LPCVD, and/or sputtering deposition techniques are used to deposit dielectrics including SiO₂, SiNx, SiC, Al₂O₃, and AlN on top of semiconductors (as substrates) including Si, GaN, InP, and β-Ga₂O₃. A dielectric layer is formed with thicknesses in a range from 1 nm to 20 nm (or to more than 20 nm) with the aspects or steps discussed below in connection with FIG. 4. The temperature used for the interlayer deposition may vary from an ambient (or room temperature) to 900° C. The thickness of the dielectric may be measured using ellipsometry after the deposition. The final interlayer thickness may be measured using TEM after the diamond growth as shown in FIG. 5.

FIG. 4 is a process-flow diagram by which nanometers-thick thin films may be controllably fabricated and characterized for providing an interlayer material, according to certain exemplary aspects of the present disclosure. The four blocks (and corresponding steps) in FIG. 4, from left to right, include: interlayer deposition (e.g., PECVD, LPCVD, MOCVD and/or ALD), and followed by any needed etching (e.g., dry etching) for establishing or setting a desired interlayer thickness. These steps of deposition and etching may be repeated as may be appropriate, optionally with certain thickness measuring to confirm the desired TBR and/or thickness (e.g., via ellipsometry thickness measurement using Cauchy Model for transparent films). Next steps as in FIG. 4 include polycrystalline diamond growth optionally followed by TEM characterization to confirm the appropriate formation of the diamond over the interlayer. As indicated at the left end of FIG. 4, for PECVD and LPCVD methods, the films are carefully etched and measured to achieve nm control, and for MOCVD and ALD methods, films can be deposited with nm scale control.

FIGS. 5A, 5B and 5C are a set of TEM images showing realization of engineered interlayers, via display of samples' respective cross-sections to show the thicknesses of different amorphous interlayers that can be achieved according to certain exemplary aspects of the present disclosure. FIG. 5A is a TEM image of an SiO₂ amorphous interlayer with a cross-sectional thickness in a range from 2 nm to 4 nm, and FIG. 5BA shows a TEM image of another example of SiO₂ amorphous interlayer with a cross-sectional thickness in a range from 10 nm to 15 nm. FIG. 5C is a TEM image of an SiO₂ amorphous interlayer with a cross-sectional thickness or 5 nm, or in a range such as from 3 nm to 5 nm (e.g., about 4 nm).

The second exemplary engineering aspect involves nanocrystallization and amorphization of the interface using high-energy ion beams. Consistent with example methods of the present disclosure, ion sources have been used in the range of 100 eV to 10 keV. Using this aspect or method, a thin interfacial layer can be formed between the diamond and the semiconductor underneath. With a thin interlayer being engineered to act as a phonon buffer layer between the two materials for lowering TBR, the interlayer thickness can vary, for example in one experimental effort, in range from a couple nm to less than 10 nm at the lower range boundary to 100 s nm at the upper range boundary.

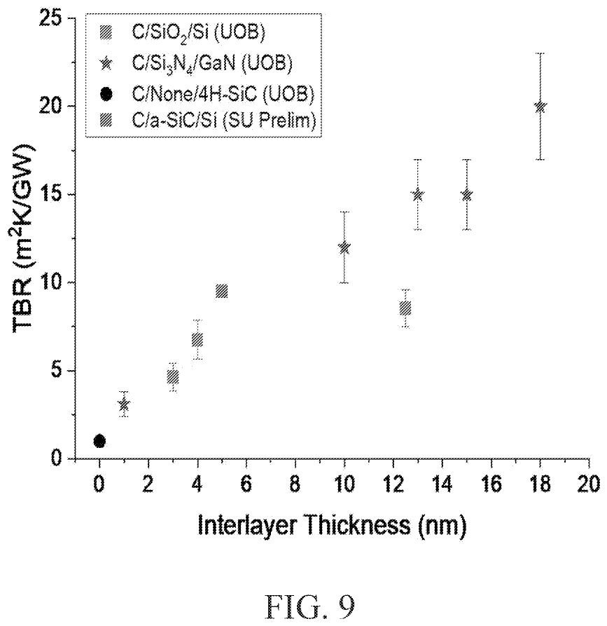

The next of these exemplary engineering aspects is crystallization of the interface using high-temperature vacuum annealing. In this aspect or method, high-temperature annealing from 800-1800° C. is used to crystallize an amorphous interlayer deposited using the above-noted first exemplary engineering aspect or method. By crystallization of the interlayer due to the better TC, it has been demonstrated that the TBR can be dropped even further, as shown via the black circle data point in FIG. 9.

The last of these noted exemplary engineering aspects involves the diffusion of carbon during diamond growth. Consistent with the above-discussed exemplary methodology and related aspects of the present disclosure, hydrogen plasma density is controlled in a chamber (as used for the diamond growth) to diffuse carbon into the substrate from 1 nm to 10 nm deep inside the substrate. The temperature of the carbon diffusion process varies between 300° C. to 1100° C. depending on the substrate and the targeted depth. This process converts a portion of the interface to SiC (in the case of SiO₂, SiNx, or Si at the interface) or to Al₄C₃ (in the case of AlN or Al₂O₃ at the interface).

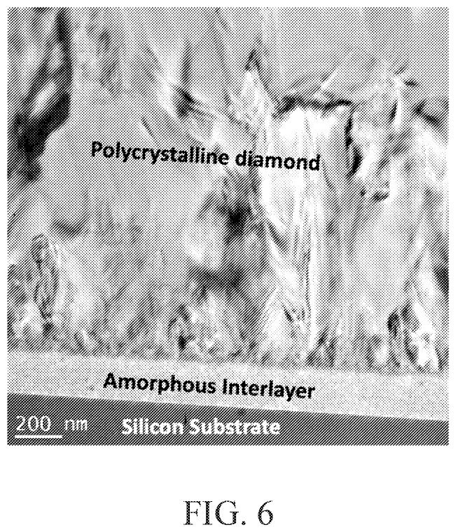

FIG. 6 is a TEM image, of an example experimental device highlighting a C/Si interface after exposure to an ion beam, according to certain exemplary aspects of the present disclosure.

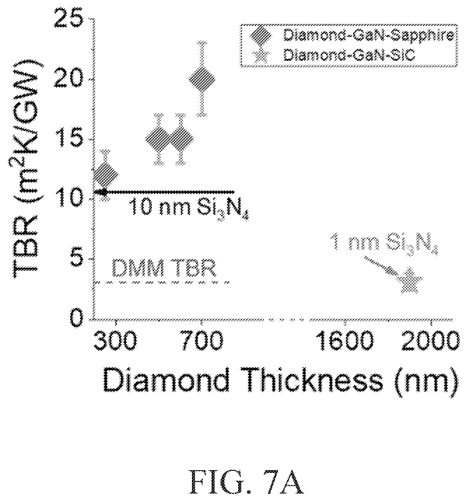

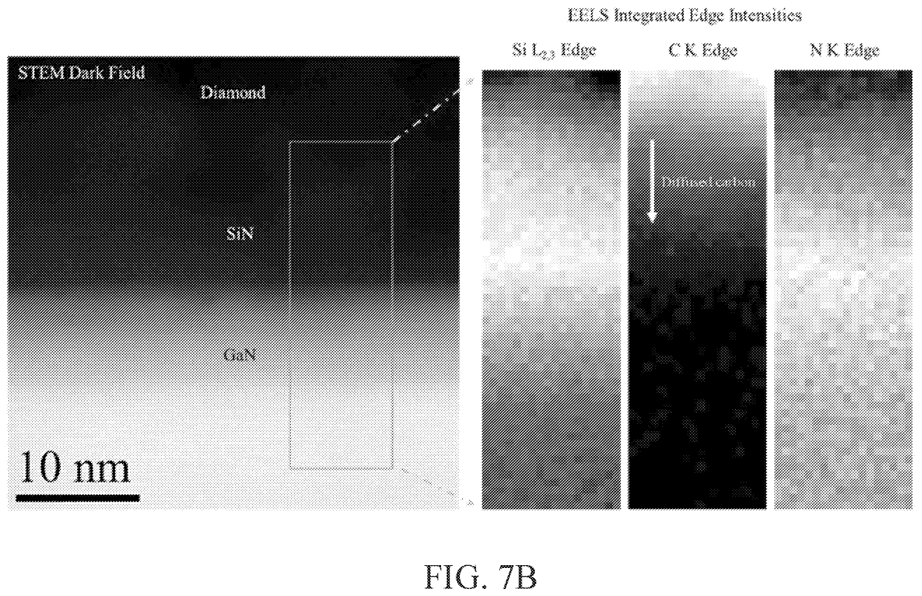

FIGS. 7A and 7B are a set of diagrams characterizing thermal behavior of an example experimental device with a particular experimental interlayer, according to certain exemplary aspects of the present disclosure. FIG. 7A shows a graph of differing thermal boundary resistances vs. diamond thicknesses, with the dashed line (“DMM TBR”) referring to a level associated with the diffuse-mismatch (DMM) predictions. FIG. 7B shows EELS characterization of a C/SiN/GaN interface or interlayer with C diffusion into SiN, for forming a SiC transition layer. The inset corresponds to the EELS edge intensities of diamond with: the first (left) image being expanded to show, for SiL2,3 Edge, a representative of Si atoms maximum on the locations with yellow color (corresponding to the lighter middle region above and somewhat below the SiN—GaN interface); the next (middle) image being expanded to show, for C K Edge, a representative of carbon atoms maximum on the locations with yellow color (corresponding to the upper portion of the inset which is well above the SiN—GaN interface); and the image to the far right being expanded to show, for N K Edge, a representative of nitrogen atoms maximum on the locations with yellow color (corresponding to the lighter middle region above and below the SiN—GaN interface).

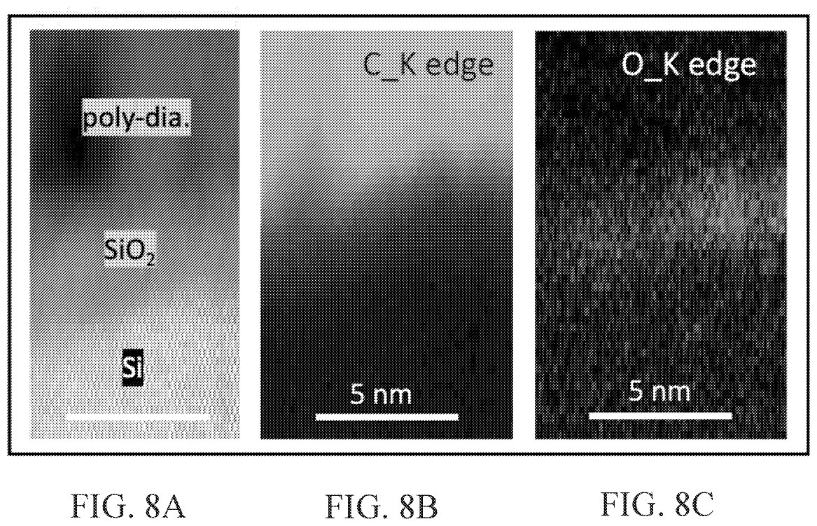

FIGS. 8A, 8B and 8C are a set of three images showing EELS analysis with cross-sectional views of three different experimental samples respectively shown, according to certain exemplary aspects of the present disclosure. As indicated in these images, using EELS imaging, the precise thickness of SiO₂ can be distinguished based on the detection of Oxygen, and slight diffusion of C into the SiO₂ can be observed as well. FIG. 8A corresponds to one such sample in which TEM image at the interface between diamond, SiO₂, and Si, FIG. 8B corresponds to the second of the samples in which EELS 2D mapping of carbon atom distribution at the interface, and FIG. 8C corresponds to the third of the samples in which EELS 2D mapping of oxygen atom distribution at the interface.

FIG. 9 is a graph showing thermal boundary resistance vs. interlayer thickness associated with different experimental samples, according to certain exemplary aspects of the present disclosure. As indicated in the key of the graph of FIG. 9, these experimental samples include as the diamond-interlayer-substrate materials: S/SiO₂/Si). C/Si₃N₄/GaN; C/None/4H—SiC; and C/a-SiC/Si. All the samples were prepared and fabricated at Stanford.

As indicated in the plotted entries of the graph, reducing interlayer thickness results in lower TBR between diamond and any semiconductor, and crystalizing the interlayer resulted in the lowest possible TBR between diamond and SiC as 1 m²K/GW. In some instances, by controlling the interlayer-material thinness (i.e., limiting the thickness), via at least one of amorphous dielectric deposition and crystalline dielectric deposition, the TBR is realized as being 3 or less, and depending on the material stack the TBR can be higher than 3 as well. For example, while forming the interlayer-material thinness via at least one of amorphous dielectric deposition and crystalline dielectric deposition, such engineering can be implemented by controlling the thickness to realize the upper limit with the phonon transport loss being mitigated for a target or corresponding TBR, which may be linked to or set as a function of the thinness and/or material configuration of the interlayer material; in such instances and depending on the thinness and/or such configuration (e.g., the material composition and/or stacking of layers engineered to form the interlayer), the TBR can be set so as to be not greater than 3, or greater than 3). Note: unless otherwise specified, the unit of measure used in characterizing a TBR is m²K/GW.

Also according to the present disclosure, using such manufacture-related methodology, various semiconductor structures and/or devices may be characterized (post manufacture or through partial manufacture) as involving deposited materials and/or etched materials by way of: in the case of deposition (e.g., as opposed to diffusion which would show a gradual profile as with the carbon diffusion of FIGS. 3A-1 and 3A-2), different chemistries of the materials with transitions between the chemistries being apparent under TEM imaging or other (e.g., chemical-based) analysis, and in the case of etching (e.g., dry etching), an etched surface which would show a degree or roughness or smoothness depending on the type of etching chemistry used.

### FURTHER RELATED EXPERIMENTAL EFFORTS AND/OR ADDITIONAL MORE-DETAILED EXAMPLES

For further information regarding various aspects of the present disclosure (e.g., exemplary structures, layered materials, dimensions, abrupt and non-abrupt comparisons, TBR- and layer-thickness (or -thinness) related measurements, heat-transport efficiencies, phonon-related overlap and/or transport loss, etc.), reference may be made to the following experimental studies (as described below) and it will be appreciated that aspects, features and the like from such experimental studies can be combined with features of another figure or example embodiments (hereinbelow or in connection with the preceding discussion) even though the combination is not explicitly shown or explicitly described as a combination, and each such combination may be considered as combinational aspects of the present disclosure. In support of the present disclosure, experimental efforts and/or additional more-detailed examples have been successfully reduced to practice and relate to the above-noted aspects (and others) of the present disclosure, as further elaborated on and supported in connection with the following discussion.

Some of these aspects, experimental efforts and/or additional more-detailed examples are provided in the discussion immediately following. Results conducted in connection with this work reveals that precise interlayer engineering below 4 nm can lead to TBRs lower than the diffuse-mismatch (DMM) theory, down to 2.13 m²K/GW. For some of this work, Si substrates were used with SiC developed with GaN material-technology. Experimentally SiC deposition was finely tuned to achieve 4-8 nm interlayers deposited on Si. Diamond was grown and the resulting TBRs were evaluated using multiple thermos-reflectance test-beds. These experimental and simulated results provide an example of a practical and predictive platform for thermal engineering.

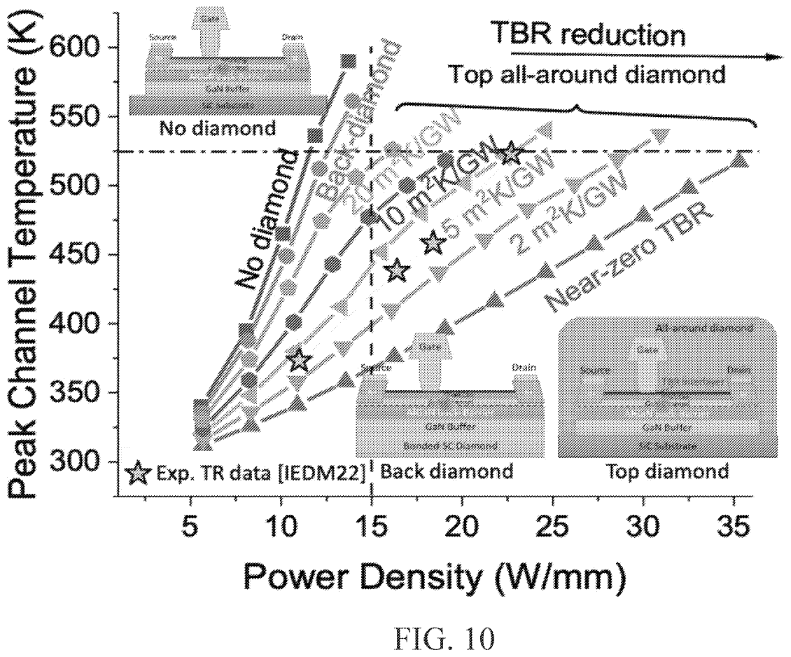

In connection with some of the experimental and simulated efforts, FIG. 10 illustrates peak channel temperature (K) versus power density (W/mm) for electro-thermal stimulation of a wide-band N-polar GaN HEMT (high electron mobility transistor) involving three cases: control HEMT without diamond, HEMT with single-crystalline diamond as the substrate, and HEMPT with 2 microns all-around PC diamond on top. Lowering the TBR between the channel and diamond heat spreader can reduce the peak channel temperature, thereby enabling reliable performance at higher power densities. Simulations show that a device functioning at 15 W/mm would have an 80 K decrease in channel temperature with a TBR of 2 versus 10 m²K/GW. Previous efforts to overlay diamond on GaN HEMT thermoreflectance data is overlayed on this plot, lying in the correct range of the model (TBRs being between 2 and 5 m²K/GW).

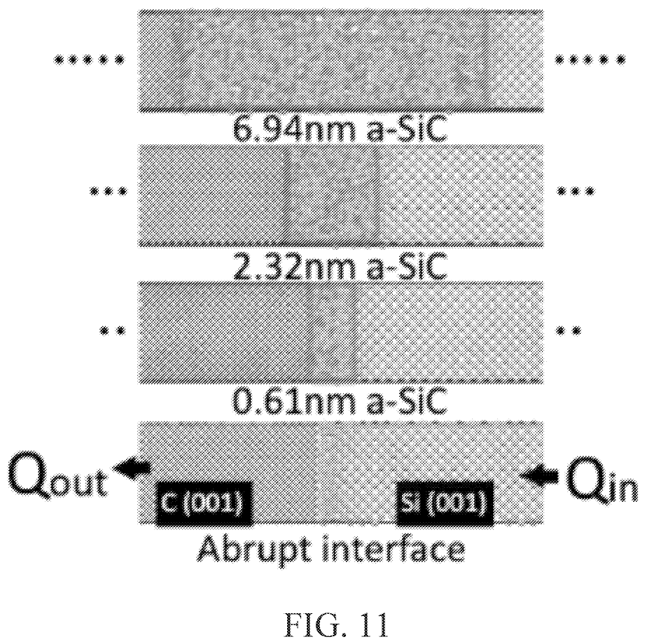

A model to predict the TBR between diamond and Si using different abrupt interfaces and interlayers was developed to understand the lower limits of TBR by interlayer engineering. The heat transport of layered systems of Si and diamond was simulated based on molecular dynamics, as indicated in FIG. 11. More particularly, FIG. 11 shows the exemplary layered system as having a heat source on Si, a heat sink on Diamond, and a constant heat flux passing through the whole system. This approach has three stages: equilibrium, transient, and steady-state. Ultimately, the temperature gradient becomes time-invariant, and based on Fourier's law of heat conduction, the total thermal resistance of the system is calculated.

To evaluate the actual TBR of an interface, bulk contributions of thermal resistance were separately calculated and subtracted from the total thermal resistance. Atomic interactions are described based on the Tersoff potential (as in Erhart, P, et al., Physical Review B 71.3 (2005): 035211), and all simulations were done using a Large-scale Atomic/Molecular Massively Parallel Simulator (LAMMPS). Among three different abrupt interface models (diamond/Si, diamond/SiC, and SiC/Si), diamond/SiC interface exhibited the lowest simulated TBR, 0.89 m²K/GW, because of its well-matched phonon density of states, and the SiC/Si exhibited relatively low as well. As has been experimentally demonstrated with these efforts, the calculated phonon density of states (PDOS) of bulk phases (based on the Tersoff potential) shows, for PMFP of amorphous SiC, that phonons over the whole frequency range (frequency range of 0-1500 l/cm) can transport effectively over less than 3 nm thick a-SiC films. In certain cases, with interlayer material being SiC and interlayer deposition conducted via PECVD, the interlayer thickness was measured as being ~4-7 nm, and with interlayer material being SiC/a-SiO₂ and interlayer deposition conducted via C diffusion ALD, the interlayer thickness was measured as being ~3 nm.

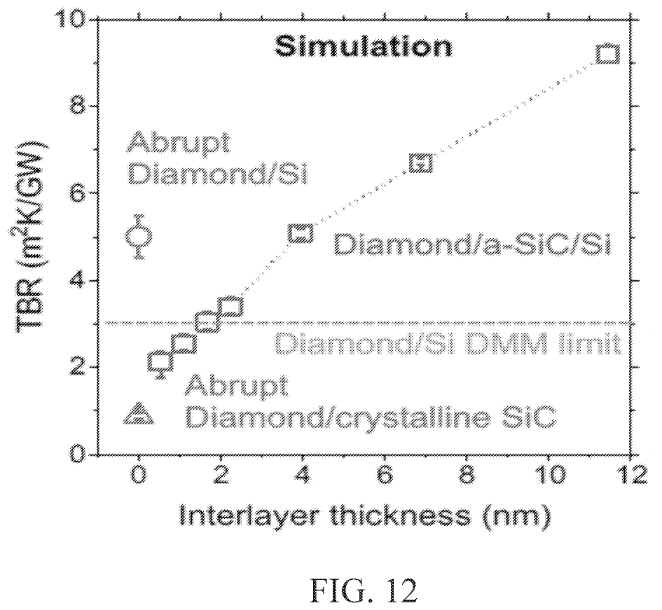

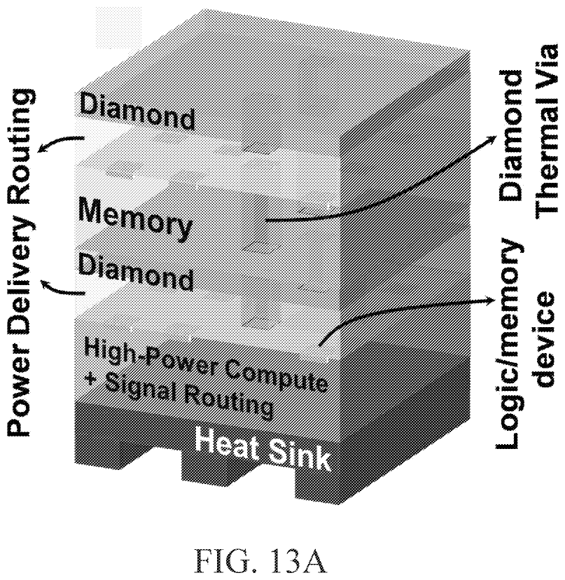

In contrast, as in FIG. 12, a direct diamond-Si interface exhibited a TBR of 5.01 m²K/GW, slightly higher than the DMM predicted 2.86-3.15 m²K/GW, which assumes random elastic scattering at the interface. This higher TBR indicates suboptimal thermal transport without any interlayer consideration for diamond on Si technology. Thus, with the insertion of a very thin amorphous-SiC interlayer (<4 nm), the diamond to Si TBR was shown to be less than that of an abrupt interface. Furthermore, the TBR is observed to increase with a-SiC interlayer thickness, which is expected due to the increased possibility of phonon scattering. Nonetheless, it was shown that having an appropriately thin a-SiC interlayer could significantly reduce the TBR by more than 50%, even below the DMM theory limit. See, e.g., FIG. 12. This can be attributed to improved phonon mode matching and phonon tunneling through the thin amorphous interlayer if thinner than PMFP as discussed above in connection with PMFP of amorphous SiC, and phonons over the whole frequency range transporting effectively over less than 3 nm thick a-SiC films.

Relating to interlayer deposition and control, and for corroboration of the predicted TBRs obtained by the models, several thicknesses of interlayer deposition was conducted on Si substrates, with various degree of crystallinity, and diamond growth were performed. SiO₂ was deposited by atomic layer deposition (ALD) and SiC by plasma enhanced chemical vapor deposition (PECVD). In this particular example of PECVD deposition, sub-10 nm thicknesses could not be achieved. Thus, a thicker interlayer was first deposited and then accurately etched to <10 nm by RIE. The thicknesses of the interlayers were measured by ellipsometry before diamond growth and measured by TEM after diamond growth. The large-grained, isotropic PC diamond grown by MPCVD is readily apparent if viewed via TEM images.

Results from the related experimentation is discussed immediately following. The average TBR diamond/SiC/Si of structures with deposited SiC interlayers (~5 nm) was measured to be 3.3 m²K/GW, low TBR supports the hypothesis that SiC is a key buffer material. Additionally, the extremely low TBRdiamond/SiC measured between diamond and crystalline 4H—SiC, <1.0 m²K/GW, was nearly identical to the simulated value and reinforces the advantage of SiC for effective phonon transport with diamond. On the other hand, simulations using purely amorphous SiC interlayers predicted that at approximately 5 nm thickness, the TBR diamond/a-SiC/Si ranges from 5.09-6.68 m²K/GW, which is greater than what was observed experimentally. It was found through HAADF TEM analysis that the diamond growth caused crystallization of the deposited a-SiC, forming SiC nanocrystallites in the interlayer. As simulations have shown, engineering the crystallinity of the SiC can reduce the TBR even further. Thus, it is predicted that annealing prior to or during high-temperature diamond growth can further reduce TBR by increasing the crystallinity of a commonly amorphous interlayer as deposited. EELS analyses of these structures revealed the non-abrupt nature of the interfaces, which contribute to smooth phonon mode transitions through the interface. The core-loss spectra showed a gradual disappearance of the C_K edge sampling towards the Si substrate and the gradual appearance of the Si_L2,3 edge. Furthermore, standards for C and Si were taken at the different layers to distinguish the interlayer from the PC diamond and substrate, showing a gradual bond transition to SiC from either side of the interface. For example, in a stacked configuration with: PC-diamond over C (edge standard from PC-diamond), over C (edge standard from SiC interlayer), over Si (edge standard from SiC interlayer), over Si (edge standard from substrate), the buffer SiC layer (1-2 nm, or interlayer) provides a smooth transition from diamond to SiC, and between the phonon properties of the diamond, interlayer, and substrate material, thus reducing the probability of phonon reflection and scattering. Furthermore, samples utilizing deposited SiO₂, the standard dielectric in Si technology, resulted in a low TBRdiamond/SiC/SiO₂/Si of 4.46 m²K/GW with a 3 nm SiC/SiO₂ interlayer. Through EELS analysis of the interface, slight carbon diffusion (~2 nm) into the SiO₂ layer was observed, resulting in the formation of a thin interfacial SiC layer (e.g., observed previously and discussed herein such as in connection with SiNx/GaN). While TBRdiamond/SiC/SiO₂/Si was higher than TBRdiamond/SiC/Si, it was still lower than that of the diamond on Si without any interlayer engineering (TBRdiamond/Si=7.2±0.8 m²K/GW). For such limited example embodiments seeking to minimize or set a particularly-low TBR, these experimental results demonstrate very low, and possibly the lowest previously reported, TBR values, and further demonstrate such low experimental TBRs to diamond as being achievable in Si and GaN. This elucidates the benefit of interlayer engineering, as the relatively low TBR, <5 m²K/GW achieved across different interlayer materials was found to be reproducible following the 3.1±0.7 m²K/GW TBR value first encountered in certain previous diamond experiments involving GaN.

Accordingly, the impact of interlayers for enabling efficient heat transport was first modeled and then experimentally demonstrated. Incorporating SiC interlayers, either through prediamond growth or by carbon inter-diffusion (1-2 nm) into SiC, SiNx, or SiO₂, reduced the measured TBR between diamond and the substrate. This study revealed that interlayer fine-tuning could enable record-low TBRs for phonon transport from Si and GaN to diamond heat spreaders (TBRdiamond/SiC/Si=1.89±0.18, TBRdiamond/SiC/SiO/Si=4.46±0.99, and TBRdiamond/SiC/SiNx/GaN=3.1±0.7 m²K/GW) by facilitating a smooth transition between phonon modes and DOS overlaps. Furthermore, the crystallization of a-SiC at the interface during the diamond growth was attributed to the record-low TBR value, which was below what was predicted by the simulations and extremely close to epitaxial interface TBR between diamond and 4H—SiC (<1 m²K/GW). These experiments are directly applicable to implementations involving, as some non-limiting examples, thermal engineering applications for Si, GaN RF and various RF power amplifier (PA) technologies.

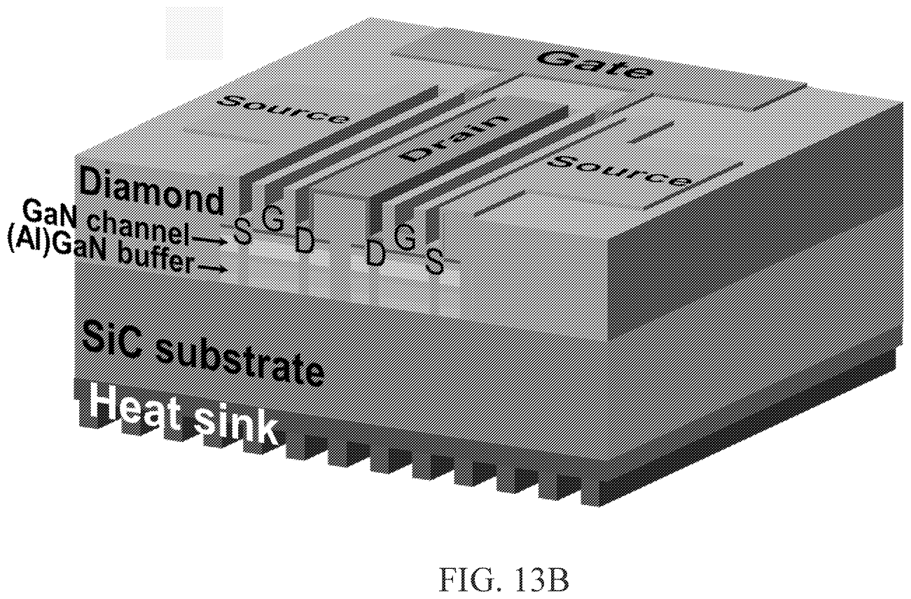

FIGS. 13A and 13B, as viewgraphs representing Si ICs and GaN-PA ICs (such as may be used in RF transistors), show that device-level thermal management can be realized by replacing the passivation layer with a single-crystal or polycrystalline diamond (due to its excellent thermal conductivity of 300-2200 W/m/K), in Si ICs, the diamond can be incorporated into the back-end-of-line (BEOL) as a heat spreader, and with an interlayer material (shown in previous figures but not shown in FIGS. 13A and 13B) for an effectively lossless phonon transition through interfaces such as Gan-Diamond and Si-Diamond.

In connection with use of an interlayer in such IC-related structures, according to examples of the present disclosure, polycrystalline diamond can be integrated close to the hot spot in a device's channel/junction by low temperature (<400° C.) CVD growth to spread the heat through various phonon transport mechanisms (diffusive or ballistic) to the heat sink. Since achieving a perfect interface (epitaxial covalent bonding) between diamond and other semiconductors, such as Si, GaN, InP, and β-Ga₂O₃, is extremely difficult due to their lattice and coefficient of thermal expansion (CTE) mismatches, interface engineering between these semiconductors and diamond is needed. The formation of a thin interlayer between the two materials can serve two primary purposes. First, an interlayer is necessary in certain materials, such as GaN, to mitigate the lattice and CTE mismatch between diamond and GaN. It serves as a stress relief layer, which enhances diamond adhesion, and as a protective layer (against H-plasma) for the semiconductor surface during diamond growth. Second, the interlayer plays a crucial role in thermal transport. As indicated previously, the third is the combination of diamond (with its high thermal conductivity) and engineering the structure for an effective TBR between the diamond and the device channel/junction material.

Some of these aspects, experimental efforts and/or additional more-detailed examples are discussed below.

In certain related experimental efforts according to the present disclosure, it has been realized that the phonon loss at the interface can be optimized or minimized (for a lower TBR) and that this requires precise interface engineering which involves careful deposition and/or material removal efforts such as by etching. In a perfectly smooth and abrupt interface (acoustic mismatch (AMM) theory), the frequency and wavenumber of the k vector are required to be the same for a phonon to transfer across the interface seamlessly. In reality, the interface is relatively rough at non-cryogenic temperatures, and the diffuse mismatch (DMM) model is more appropriate. Here, phonons are assumed to be diffusely scattered at the interface and have no memory of their modes. Thus, the phonon density of states (PDOSs) overlap is proportional to the likelihood of phonon transfer through the interface. The PDOS does not overlap well between Si or GaN and Diamond across higher frequency ranges. Thus, adding phonon bridges between the two materials is necessary. Using an amorphous interlayer leads to phonon mode mixing, which allows more efficient phonon transport across an interface, as the initial phonon mode from Si or GaN can be modified and ultimately have better alignment than with of diamond. The amorphous interlayer leads to remarkable phonon mode conversions, such as longitudinal acoustic (LA) to transverse acoustic (TA), TA to LA, and LA to transverse optical (TO) conversions. These conversions in amorphous materials, where the phonon modes are not well-defined, help the phonons transport from one material to the other with less loss. The conversion results from the strong anharmonicity of the interatomic potential, which leads to the mixing of different phonon modes. SiC provides a larger PDOS overlap between Si and diamond, letting a more significant portion of the phonons cross the interface for phonon mode mixing in the amorphous interlayer. Compared to a-Si, which does not provide enough PDOS overlap between diamond and Si, a-SiC can make a more efficient phonon bridge, and SiO₂ also overlaps with Si and diamond, which is beneficial for certain example implementations of the present disclosure. For example, for phonon bridging between diamond and GaN, through experimentation leading to the present disclosure, it has been shown that SiNx can provide a TBR of 3.1 m²K/GW and in some instances a TBR of slightly less than 3 m²K/GW, for specific combinations. SiNx not only expands the frequency overlap but also enhances diamond adhesion to the surface by SiC formation during the diamond growth (SiC formation was observed with SiO₂ interlayer as well). Besides SiNx, a-SiC can also make a phonon bridge between diamond and GaN due to the frequency overlap from 20 to 30 THz.

In the case of the GaN/diamond interface, even though there is an overlap in PDOS between 20 to 30 THz, the weak van der Waals bonding deteriorates the phonon transitions due to the formation of nano-sized air gaps and delamination because of H-plasma damage and a large CTE mismatch. For phonon bridging between diamond and GaN, efforts for the present disclosure have shown that SiNx can provide a record-low TBR of 3.1 m²K/GW, for the given combination. SiNx not only expands the frequency overlap but also enhances diamond adhesion to the surface by SiC formation during the diamond growth (SiC formation was observed with SiO₂ interlayer as well). Besides SiNx, a-SiC can also make a phonon bridge between diamond and GaN due to the frequency overlap from 20 to 30 THz.

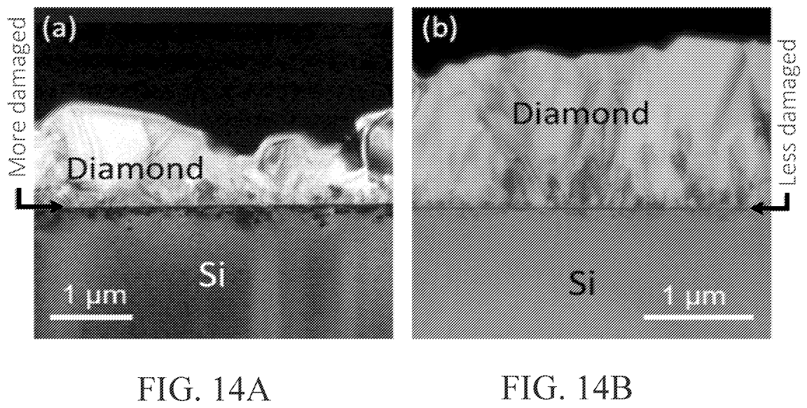

To elucidate the interface between diamond and differing interlayers and substrates, extensive TEM (transmission electron microscopy) imaging along with EELS (electron energy loss spectroscopy) analysis was conducted. First, when the polycrystalline diamond was grown directly on a Si substrate with no engineered interlayer, the presence of a native oxide measured by ellipsometry to be ~1.4 nm was shown to improve diamond nucleation and growth by possibly lowering the hydrogen penetration that occurs in the diamond growth chamber into the substrate, as illustrated in FIG. 14B. In contrast, in the case in which the native oxide was removed by HF etch prior to diamond seeding, TEM images show that substantial etching damage occurred on the Si substrate during diamond growth (FIG. 14A). Furthermore, the final average diamond thickness after growth was only 0.3-0.5 μm compared to the 1.5-1.8 μm-thick diamond that was achieved using the same growth conditions on the Si substrate with a native oxide. This result confirms the important role of the interlayer in the heterogeneous growth of diamonds and the protection of the substrate given the seeding and growth parameters used in such experimentation. It is also noted that varying pre-growth treatments, plasma parameters, and CH4 percentage can also play a role in the interface roughness and SiO₂ etching during the diamond growth.

More particularly, FIG. 14A is a TEM image of polycrystalline diamond grown on HF-treated Si substrate in which the native oxide was removed, and FIG. 14B is a TEM image of polycrystalline diamond grown on a Si substrate with its native oxide and identical growth conditions to that of FIG. 14A. In addition to native SiO₂, four different thicknesses of ALD SiO₂ were deposited as interlayers prior to the diamond growth. The thickness of SiO₂ was measured by TEM after the growth in which the thickness was varied from 3-12.5 nm. The detailed EELS profile of the interface of the sample (FIG. 14A), with 3 nm SiO₂, reveals a non-abrupt nature at the interface and confirms carbon diffusion into the SiO₂ layer, forming a SiC buffer layer between diamond and SiO₂. By using a core-loss EELS spectrum summed over rectangular regions, one can identify regions (from a top diamond region, to upper and lower interlayer regions, to the bottom Si substrate region) useful for analyzing the respective chemistries of the material layers in which: C and O are detected with a prominent carbon peak (~285 eV) observable (decreasing in intensity from diamond and moving down into the interlayer regions to silicon), and with an oxygen peak detectable from the interlayer regions, thereby confirming the existence of both elements in the interlayer. Finally, in the lowest region, there is neither a carbon nor oxygen peak, as expected in the Si substrate. The lack of Si and oxygen in the second region might be due to the carbon and hydrogen diffusion into the amorphous layer, followed by removal of Si and oxygen after reacting with hydrogen radicals. In such experimentation, this inter-diffused carbon bonds with Si and forms an interfacial SiC layer (2-3 nm) between the diamond and SiO₂. The interdiffusion of carbon has been shown, via the efforts of the present disclosure, to provide a smooth transition between the phonon properties of the diamond, interlayer, and substrate material, thus reducing the probability of phonon loss (reflection/scattering), as explained hereinabove.

When using HDPCVD SiC as an interlayer, TEM images showed that the SiC was partially crystallized (fringes observed at the interface) during the diamond growth. Fast Fourier Transform (FFT) analysis confirmed that the interlayer contained SiC nano-crystallites based on the identified diffraction spots. The amorphous nature of the deposited SiC prior to the diamond growth was validated using similar techniques that showed a lack of diffraction spots in the SiC. Thus, it is inferred that the crystallization occurred during diamond growth due to the atomic hydrogen plasma and relatively high-temperature conditions (500-600° C.) in the chamber.

Similar to the SiO₂ interlayer samples, the diamond/SiC/Si interface was shown to have gradual and smooth compositional transitions from the EELS analysis. The core-loss spectra show gradual disappearance of the C_K edge sampling towards the Si substrate and the gradual appearance of the Si_L2,3 edge. Furthermore, the Si peak shift from 102 eV to 105 eV in the interlayer indicates the formation of SiC in certain but not all of the segments.

In the case of experimentation with the diamond/SiC/GaN interface, most of the interface remained amorphous due to the slightly lower growth temperature (450-500° C.). Furthermore, from the EELS data, the existence of carbon overlaps with Si, which is expected from the SiC interlayer but also from diffusion from the diamond. On the other side of the interface, Ga and N overlap with the Si from the interlayer. Thus, for the ~6 nm that forms the interface and buffer layers, there is apparent intermixing of the different elements present in the diamond, interlayer, and GaN substrate.

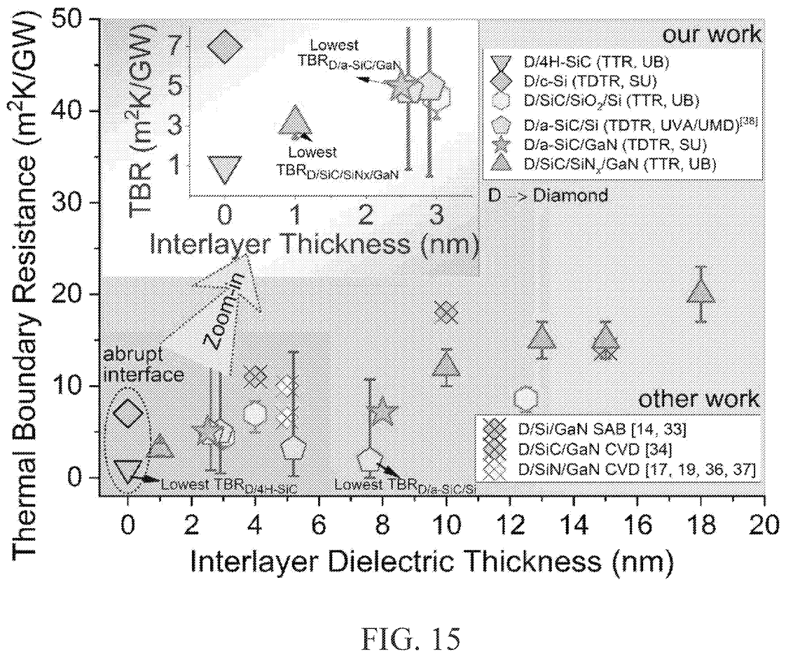

FIG. 15 presents a graph-based summary of measured TBRs for diamond-Si, diamond-GaN, and diamond-SiC with different interlayer dielectrics according to examples of the present disclosure. The details of each material system are broken down below.

For diamond/4H—SiC, due to the phonon frequency overlap between diamond and 4H—SiC, the phonons transport mostly unimpeded between the two materials and maintain their modes. SiC has a high defect density near the interface and narrow bands with different crystal structure at the top (~1.5 nm). FFT and stacking sequence (ABC) indicate a thin band of 3C—SiC (<1.5 nm) in some regions at the surface. Crystalline cubic diamond forms directly at the interface on top of 3C—SiC, and there is little or no sign of any amorphous phase in between. This abrupt interface provides stable single C—C bonds that can lower the phonon loss probability through the interface with minimal reflection. The diamond/3C—SiC/4H—SiC TBR was measured using TTR method to be ~1 m²K/GW. This is the closest experimental value to the MD-simulated values of 0.39 m²K/GW and 0.89 m²K/GW (as appears to have been previously reported).

For diamond/Si, two different interlayers, SiO₂ and a-SiC, were utilized for the Si substrate. Reducing the SiO₂ thickness, resulted in TBR reduction <5 m²K/GW with a 3 nm SiO₂ interlayer. This has been previously reported as thicker interlayers which contribute to the thermal resistance due to higher scattering probability, especially if they have low thermal conductivity, like SiO₂ (TC: ~1 W/m/K). However, the resulting TBR is lower than the direct diamond-Si TBR, measuring around 7 m²K/GW. Thus, the importance of a non-abrupt phonon-mixing interlayer to transmit phonons across the diamond/Si interface is confirmed, consistent with aspects of the present disclosure. Furthermore, at thicknesses less than 3 nm, phonon tunneling through the amorphous interlayer appears to be an important phenomena contributing to improved phonon transport.

Remarkably, when using a-SiC between diamond and Si as an interlayer dielectric, the samples with thinner interlayers did not necessarily demonstrate lower TBRs like in SiO₂. Upon TEM examination of the interface, it was found that the a-SiC becomes partially crystallized during diamond growth the atomic structure rearranges to form a thin 3C—SiC layer. This rearrangement of the SiC atomic structure can happen throughout the high-temperature diamond growth process or during the early stages of nucleation; however, more investigations are helpful for a thorough understanding of the SiC crystallization, and its contribution to phonon mode mixing. The thinner SiC interlayer (2.6 nm) was crystallized entirely, and no a-SiC remained, while the thicker layer (7.2 nm) was partially crystallized with a remaining of 2-3 nm a-SiC. It is believed that the remaining a-SiC allows for phonon mode mixing between diamond and Si, facilitating the transmission of phonons across the interface. Thus, the thicker SiC interlayer resulted in an average TBR of 1.89 m²K/GW between diamond and Si (e.g., another apparent lowest relative to those thus-far reported).

In one example, direct diamond CVD growth on GaN resulted in a minimum TBR of ~20 m²K/GW. This large value is due to the weak van-der-Waals bonding between diamond and GaN and the lack of phonon frequency overlap between the two materials. As shown in FIG. 15, reducing the thickness of SiNₓ and SiC between diamond and GaN resulted in lower TBR. In this particular study, PECVD and MOCVD SiNₓ are used for forming the interlayer between diamond and GaN. To minimize the diamond-GaN TBR, an ultra-thin SiNₓ <3 nm (to enable phonon tunneling) is required. PECVD SiNₓ was completely damaged and etched away during diamond growth due to H₂-plasma exposure. On the other hand, only 1 nm of the MOCVD SiNₓ was etched during growth, but the remaining interlayer survived the growth process and protected the interface. The diamond/SiNₓ/GaN TBR reached its lowest value at 3.1 m²K/GW with an ultra-thin SiNₓ interlayer (~1 nm) as measured by TEM, and ~1 nm inter-diffused SiC layer measured by EELS, which closely aligns with DMM theory. On one side, SiNₓ forms a strong bond with GaN, and carbon diffusion during diamond growth, which leads to transformation of SiNₓ into SiC on the other side. The newly formed SiC layer establishes a robust covalent bonding (C—C single bonds) with diamond, enhancing adhesion while enabling gradual change in stoichiometry along the interface. This gradual material transition not only mitigates the coefficient of thermal expansion (CTE) mismatch between diamond and GaN but, more importantly, facilitates phonon transport through the interface by providing phonon frequency overlap, with both diamond and GaN, and phonon mode conversion, resulting in lower TBR.

The thin SiC layer that forms during the diamond growth by carbon diffusion into the SiNₓ, next motivated the use of SiC as the interlayer before the growth. Unlike the diamond/SiC/Si material system, the SiC between diamond and GaN was not crystallized and remained amorphous through the growth. This resulted in decreasing TBR with the decrease in a-SiC thickness, which reaches the values of <5 m²K/GW. In connection with such experimental efforts according to the present disclosure, it has also been shown that a-SiC (like SiNx) can also provide a low thermally resistive interface between diamond and GaN.

Also according to the present disclosure, it has been shown that the TBR can have an important impact on the channel/junction temperature in such ICs, including so-called three-dimensional (3D) ICs. It has been reported that ultra-dense 3D ICs with 100 nm horizontal pitch between vertical vias could achieve 1000× energy-delay product benefits versus those built with conventional technologies that enable via pitches of 1-10 μm. With conventional cooling, these 3D ICs are thermally limited to only one layer of high-power compute. However, enabling multiple layers of stacks, simultaneously active compute through better cooling could unlock scaling of these massive benefits to even larger workloads. However, even if heatsinks improve, ultra-dense 3D ICs are limited by their challenging thermal environment. In these systems, high-power compute hotspots are buried in tall stacks of thermally resistive BEOL materials, such as the ultra-low-K interlayer dielectric (ILD), which can have thermal resistance 5× higher than SiO₂. Diamond's high thermal conductivity and low dielectric constant make it a promising replacement dielectric material, and improving its TBR with Si could further increase its benefits in a Si-based 3D IC.

It has also been reported that 3D thermal scaffolding, as a technique, can help to exploit the advantages of diamond and achieve massive temperature reduction (e.g., a 10× reduction in peak temperature rise with 12 stacked compute tiers) by selectively patterning diamond layers and scaffolding via structures. In certain of these examples, diamond is used as the heat-spreading dielectric only in the upper power delivery network layers, which are close to hotspots and are less performance-critical than the lower signal routing layers, and scaffolding vias are co-placed with the diamond to channel the heat down to the heatsink.

Also according to the present disclosure, the impact of diminishing the TBR between the diamond BEOL layers and Si on such 3D IC systems has been investigated with COMSOL simulation. The effect of reducing the TBR_{Si-Diamond} from 20 to 1.89 m²K/GW (which may be the lowest average value reported so far) on the peak temperature has been studied according to the present disclosure, for three cases: baseline with no diamond BEOL or scaffolding via, diamond BEOL with no via, and scaffolding with diamond via. It was shown that decreasing the TBR reduces the temperature rise due to the 3D layers (i.e., the peak temperature difference from ambient assuming a perfect heatsink) by an offset that does not strongly depend on the number of tiers but grows larger as the hotspot becomes smaller. This is because heat spreading due to diamond occurs after the heat enters the diamond layer through the diamond/Si interface. Because smaller hotspots require more heat spreading, they are impacted more by improving TBR.

For GaN Pas, the TBR between diamond and GaN plays an essential role in determining the channel temperature under operation. Reducing the diamond/GaN TBR reduces the channel temperature and results in high power before reaching the maximum operating temperature (see ATLAS User's Manual, SILVACO International, 2004). This simulation was calibrated with the experimental data reported in R. Soman, M. Malakoutian, B. Shankar, D. Field, E. Asko, N. Hatui, N. J. Hines, S. Graham, U. K. Mishra, in 2022 International Electron Devices Meeting (IEDM), San Francisco, CA, USA, 2022, pp. 30.8.1-30.8.4. The device with 3D all-around diamond and a TBR <5 m²K/GW between diamond and GaN, as also previously reported, reached ~23 W/mm at 525 K, while for the same structure with a TBR of 20 m²K/GW it can only reach ~16 W/mm. However, according to experimental efforts involving examples of the present disclosure, it has been shown that both SiC and SiNₓ can reduce the TBR to <5 m²K/GW, which is helpful, if not necessary, for higher power output and more reliable operation (e.g., before reaching thermal runaway).

Based on the preceding discussion of such experimental efforts according to the present disclosure, several dielectric materials have been investigated as thermal interface buffers in structures such as at GaN/diamond and Si/diamond interfaces. The TBR between diamond and Si can be lowered by engineering the interlayer thickness (e.g., deposition, material removal, etc.) and the crystallinity percentage, and in some instances, achieving an average TBR value of 1.89 m²K/GW, which is lower than the DMM theory predictions. Herewith, it has also been shown that using either SiNₓ or a-SiC can bring down the TBR to <5 m²K/GW between diamond and GaN. Interface engineering strategy can effectively lower the channel/junction temperature in various material systems, not only in Si and GaN technologies but also in other technologies such as but not limited to AlN, InP, and Ga₂O₃

It is recognized and appreciated that as specific examples, the above-characterized figures and discussion are provided to help illustrate certain aspects (and advantages in some instances) which may be used in the manufacture of such structures and devices. These structures and devices include the exemplary structures and devices described in connection with each of the figures as well as other devices, as each such described embodiment has one or more related aspects which may be modified and/or combined with the other such devices and examples as described hereinabove may also be found in the Appendices of the above-referenced Provisional Application.

The skilled artisan would also recognize various terminology as used in the present disclosure by way of their plain meaning. As examples, the Specification may describe and/or illustrates aspects useful for implementing the examples by way of various semiconductor materials/circuits which may be illustrated as or using terms such as layers, blocks, modules, device, system, unit, controller, and/or other circuit-type depictions. Such semiconductor and/or semiconductive materials (including portions of semiconductor structure) and circuit elements and/or related circuitry may be used together with other elements to exemplify how certain examples may be carried out in the form of structures, steps, functions, operations, activities, etc. It would also be appreciated that terms to exemplify orientation, such as upper/lower, left/right, top/bottom and above/below, may be used herein to refer to relative positions of elements as shown in the figures. It should be understood that the terminology is used for notational convenience only and that in actual use the disclosed structures may be oriented different from the orientation shown in the figures. Thus, the terms should not be construed in a limiting manner.

Based upon the above discussion and illustrations, those skilled in the art will readily recognize that various modifications and changes may be made to the various embodiments without strictly following the exemplary embodiments and applications illustrated and described herein. For example, methods as exemplified in the Figures may involve steps carried out in various orders, with one or more aspects of the embodiments herein retained, or may involve fewer or more steps. Such modifications do not depart from the true spirit and scope of various aspects of the disclosure, including aspects set forth in the claims.

1. An apparatus comprising:
a substrate material susceptible to collecting or generating heat due to electrical conductivity near or in the substrate material;
a diamond material to spread and transfer heat from the substrate material; and
an interlayer material, characterized as having a TBR (thermal boundary resistance) and an interlayer-material thinness across the interlayer material between the substrate material and the diamond material, the interlayer-material thinness having an upper limit engineered via a material deposition technique to mitigate phonon transport loss for realizing a target or a corresponding TBR associated with the interlayer material.

2. The apparatus of claim 1, wherein the interlayer material is characterized by at least one smooth transition in material phases to match, on opposing sides of the interlayer material, one of or a combination of the following: phonon group velocity, phonon frequency, or phonon mode.

3. The apparatus of claim 1, wherein the substrate material includes a carbon-diffused portion, along a side of the substrate material facing the diamond material, the carbon-diffused portion having a cross section characterized by a thinness parameter in a range from about 1 nm to about 10 nm.

4. The apparatus of claim 1, wherein interlayer material acts as a stress relief layer which enhances adhesion force caused by lattice and coefficient of thermal expansion (CTE) mismatch.

5. The apparatus of claim 1, wherein the substrate material includes an inner side having diffused carbon.

6. The apparatus of claim 1, wherein the interlayer material is a dielectric that includes SiC.

7. The apparatus of claim 1, wherein the interlayer material is a dielectric that includes AIC.

8. The apparatus of claim 1, wherein the interlayer material includes an etched portion due to the material deposition technique, and further includes one or more of the following: Al₂O₃, SiO₂, and AlN.

9. The apparatus of claim 1, wherein the interlayer material is formed as carbon-based phonon buffer with at least two immediately-adjacent material phases between which is a smooth material-phase transition to facilitate at least one phonon-related parameter being matched on opposing sides of the substrate material and the diamond material.

10. The apparatus of claim 1, wherein the substrate material is a semiconductor material.

11. The apparatus of claim 1, wherein the substrate material is a not a semiconductor material.

12. The apparatus of claim 1, wherein the substrate material is a semiconductor material including at least one of the following: Si, SiC, GaAs, GaN, InP, and β-Ga₂O₃.

13. The apparatus of claim 1, wherein the interlayer material, formed by the material deposition technique, includes an amorphous dielectric portion.

14. The apparatus of claim 1, wherein the interlayer material, formed by the material deposition technique, includes a crystalline dielectric portion.

15. The apparatus of claim 1, further including at least one semiconductor device, integrated with or thermally coupled to the substrate material, wherein at least one semiconductor device is a cause of the substrate material being susceptible to collecting or generating heat due to electrical conductivity near or in the substrate material.

16. A method involving a diamond material to spread and transfer heat from a substrate material that is susceptible to collecting or generating heat due to electrical conductivity near or in the substrate material, the method comprising:
providing an interlayer material, characterized as having a TBR (thermal boundary resistance) and an interlayer-material thinness across the interlayer material between the substrate material and the diamond material, wherein the interlayer-material thinness has an upper limit engineered via a material deposition technique to mitigate phonon transport loss for realizing a target or a corresponding TBR associated with the interlayer material.

17. The method of claim 16, further including causing heat to collect or generate due to electrical conductivity near or in the substrate material, and using the interlayer material to transport phonons across a portion of the interlayer material associated with the interlayer-material thinness.

18. The method of claim 16, further including controlling the interlayer-material thinness, via at least one of amorphous dielectric deposition and crystalline dielectric deposition, to realize the TBR as being not greater than 3 m²K/GW.

19. The method of claim 16, further including controlling the interlayer-material thinness, via at least one of amorphous dielectric deposition and crystalline dielectric deposition, to realize the upper limit with the phonon transport loss being mitigated for realizing the target or the corresponding TBR, as a function of the thinness of the interlayer material, wherein the TBR is greater than 3 m²K/GW.

20. (canceled)

21. The method of claim 16, further including causing carbon to be diffused into the substrate material by a process through which hydrogen plasma density in a chamber is controlled to diffuse carbon into the substrate over a depth range that is from about 1 nm to about 10 nm, and causing the interlayer material to crystallize during growth of the diamond material.

22.-24. (canceled)
